(19) United States
(12) Patent Application Publication
(10) Pub. No.: US 2025/0321491 A1
(43) Pub. Date: Oct. 16, 2025

(54) Compositions For Removing A Photoresist From A Substrate And Uses Thereof

(71) Applicant: Versum Materials US, LLC, Tempe, AZ (US)

(72) Inventors: YUANMEI CAO, Carmel, IN (US); LILI WANG, Chandler, AZ (US)

(21) Appl. No.: 18/556,199

(22) PCT Filed: Apr. 19, 2022
(86) PCT No.: PCT/US22/71792

§ 371 Date: Oct. 19, 2023

Related U.S. Application Data
(60) Provisional application No. 63/182,334, filed on Apr. 30, 2021.

(51) Int. Cl. G03F 7/42

(52) U.S. Cl. CPC G03F 7/425

(57) ABSTRACT

The disclosed and claimed subject matter relates to photoresist stripper solutions that include (i) one or more inorganic bases; (ii) two or more organic solvents; (iii) one or more corrosion inhibitors and can optionally include (iv) one or more secondary solvent(s).

### BACKGROUND

### Field

The disclosed and claimed subject matter relates generally to compositions having the ability to effectively remove photoresists from substrates, and to methods for using such compositions. The compositions disclosed are stripper solutions for the removal of photoresists that may be essentially free of DMSO, NMP and TMAH, and preferably have compatibility with metals and passivation materials such as polyimide.

### Related Art

Photoresist strippers for removal of thick photoresists used in wafer level packaging typically include different combinations of solvents, amines, quaternary ammonium hydroxides, inorganic hydroxides, co-solvents, corrosion inhibitors, and other additives. Many products for this application include DMSO or NMP as the solvent plus amines or quaternary ammonium hydroxides or both. Tetramethylammonium hydroxide (TMAH) is the most commonly used quaternary ammonium hydroxide due to its lower cost and better performance than other quaternary ammonium hydroxides. However, there are well known potential health effects associated with TMAH. An alternative to TMAH containing stripper compositions is desirable.

Inorganic bases, especially alkali metal hydroxides, provide advantageous properties when used in photoresist strippers, without the potential health effects associated with TMAH. They have low costs and good thermal stability, leading to photoresist strippers with longer bath lifetimes compared to photoresist strippers using TMAH. One issue associated with alkali metal hydroxides, however, is their tendency to react with carbon dioxide from the atmosphere to produce its carbonate salt. Carbonate salts are water soluble, but typically not very soluble in organic solvents. As such, photoresist strippers using alkali metal hydroxide typically have precipitation or sludge issues with formation of carbonate salt crystals that are insoluble in the organic solvents of the stripper; this causes tool clogging and potentially imposes safety concerns over the operation of the tool. The removal of the precipitated carbonate salts may require extra cleaning of process tools, using water to dissolve and/or rinse them away, therefore increasing the maintenance cost. As such, it is critical to solve sludge issue in organic solvent-based remover using inorganic bases especially alkali metal hydroxide.

There are many stripper solutions for the removal of photoresists (e.g., U.S. Patent Application Publication No. 2019/0317409 describes a stripper solution for removing photoresist from substrates that includes primary solvent, secondary solvent, inorganic base, amine and corrosion inhibitor). Improved stripper solution compositions are required by wafer manufacturers' increasing demands for improved performance. With various materials used in the substrates for various functions, strippers may contact those materials and thus there is a need to have the ability to remove the photoresist and compatibility with materials on the substrate that are not to be removed. Additionally, with recent restrictions on solvents used in stripper formulations, such as the restrictions on N-methyl-2-pyrrolidone (NMP) and dimethyl sulfoxide (DMSO), new formulations with more environmentally friendly solvent are needed.

### SUMMARY

This summary section does not specify every embodiment and/or incrementally novel aspect of the disclosed and claimed subject matter. Instead, this summary only provides a preliminary discussion of different embodiments and corresponding points of novelty over conventional techniques and the known art. For additional details and/or possible perspectives of the disclosed and claimed subject matter and embodiments, the reader is directed to the Detailed Description section and corresponding figures of the disclosure as further discussed below.

The disclosed and claimed subject matter is directed to photoresist stripper solutions for effectively removing or stripping a positive or negative photoresist, photoresist after an etch process, or etch residue from a substrate. The disclosed and claimed photoresist stripper solutions have particularly high loading capacities for the resist material, and the ability to remain a liquid when subjected to temperatures below normal room temperature that are typically encountered in transit, warehousing and in use in some manufacturing facilities.

The disclosed and claimed photoresist stripper solutions include inorganic hydroxides resulting in reduced carbonate crystal formation and extended bath life. The disclosed and claimed photoresist stripper solutions are free of NMP and DMSO and are particularly useful for removing both positive and negative liquid photoresists. The disclosed and claimed photoresist stripper solutions do not harm the materials present on the substrates particularly metals, silicon and passivation materials such as polyimide.

The disclosed and claimed photoresist stripper solutions include:
(i) one or more inorganic bases;
(ii) two or more organic solvents; and
(iii) one or more corrosion inhibitors.

In a further aspect, the solutions include (iv) one or more secondary solvent(s). In a further aspect of this embodiment, the solutions consist essentially of (i), (ii) and (iii). In a further aspect of this embodiment, the solutions consist essentially of (i), (ii), (iii) and (iv). In yet a further aspect of this embodiment, the solutions consist of (i), (ii) and (iii). In yet a further aspect of this embodiment, the solutions consist of (i), (ii), (iii) and (iv).

In another embodiment, the solution includes (i) one or more inorganic bases selected from NaOH, KOH and combinations thereof. In an aspect of this embodiment, the (i) one or more inorganic bases includes NaOH. In another aspect of this embodiment, the (i) one or more inorganic bases includes KOH. In another aspect of this embodiment, the (i) one or more inorganic bases includes a combination of NaOH and KOH.

In another embodiment, the solution includes (ii) two or more organic solvents where (a) the first solvent is selected from a glycol ether solvent, an ether alcohol solvent and an aromatic ring-containing alcohol and combinations thereof and (b) the second solvent is a polyol solvent (i.e., a polyhydroxyl-containing solvent). In an aspect of this embodiment, the (ii) two or more organic solvents includes a glycol ether solvent. In an aspect of this embodiment, the (ii) two or more organic solvents includes an ether alcohol solvent. In an aspect of this embodiment, the (ii) two or more organic solvents includes an aromatic ring-containing alcohol. In an aspect of this embodiment, the (ii) two or more organic solvents includes a glycol ether solvent and an ether alcohol solvent. In an aspect of this embodiment, the (ii) two or more organic solvents includes a glycol ether solvent and an aromatic ring-containing alcohol. In an aspect of this embodiment, the (ii) two or more organic solvents includes an ether alcohol solvent and an aromatic ring-containing alcohol.

In one exemplary embodiment of the disclosed and claimed subject matter, photoresist stripper solutions include:
(i) one or more inorganic bases including from about 0.5 wt % to about 5 wt % potassium hydroxide;
(ii) two or more organic solvents including:
   a. from about 30 wt % to about 90 wt % triethylene glycol monomethyl ether, and
   b. from about 5 wt % to about 30 wt % diethylene glycol; and
(iii) from about 0.01 wt % to about 5 wt % of one or more corrosion inhibitors.

In one exemplary embodiment of the disclosed and claimed subject matter, photoresist stripper solutions include:
(i) one or more inorganic bases including from about 0.5% to about 5% potassium hydroxide;
(ii) two or more organic solvents including:
   a. from about 30 wt % to about 90 wt % triethylene glycol monomethyl ether, and
   b. from about 5 wt % to about 30 wt % diethylene glycol;
(iii) from about 0.01 wt % to about 5 wt % of one or more corrosion inhibitors; and
(iv) one or more secondary solvent(s) including from about 5 wt % to about 30 wt % of a polyol solvent.

In another embodiment, the disclosed and claimed subject matter is directed to methods of using the disclosed and claimed photoresist stripper solutions to remove photoresist and related polymeric materials from a substrate. In one aspect of this embodiment, a photoresist is removed from a substrate having a photoresist thereon by contacting the substrate with one or more of the photoresist stripper solutions for a time sufficient to remove the desired amount of photoresist, by removing the substrate from the stripping solution, rinsing the stripping solution from the substrate with DI water or a solvent, and drying the substrate.

The disclosed and claimed subject matter is further directed to the use and synthesis of the disclosed and claimed chemical formulations.

In another embodiment, the disclosed and claimed subject matter is directed to electronic devices manufactured by the novel method disclosed.

Other features and advantages of the disclosed and claimed subject matter will be apparent from the following more detailed description, taken in conjunction with the example solutions which illustrate the principles of the disclosed and claimed subject matter.

The embodiments of the disclosed and claimed subject matter provide one or more of the following benefits: low precipitation of solids during use; the compositions have the ability to remain liquid at temperatures below normal room temperature and temperatures frequently encountered in transit and warehousing, and have flashpoints well above normal processing temperatures, a photoresist stripper with good cleaning-ability, high loading capacity, reduced crystallization and precipitation of alkali metal carbonate, or other alkali metal compounds, even when the stripper solution includes an alkali metal hydroxide, compatibility with metals, silicon and passivation material such as polyimide as well as extended bath life.

The order of discussion of the different steps described herein has been presented for clarity sake. In general, the steps disclosed herein can be performed in any suitable order. Additionally, although each of the different features, techniques, configurations, etc. disclosed herein may be discussed in different places of this disclosure, it is intended that each of the concepts can be executed independently of each other or in combination with each other as appropriate. Accordingly, the disclosed and claimed subject matter can be embodied and viewed in many different ways.

### Definitions

For the purposes of promoting an understanding of what is claimed, references will now be made to the embodiments illustrated and specific language will be used to describe the same. It will nevertheless be understood that no limitation of the scope of what is claimed is thereby intended, such alterations and further modifications and such further applications of the principles thereof as illustrated therein being contemplated as would normally occur to one skilled in the art to which the disclosure relates.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the disclosed and claimed subject matter (especially in the context of the following claims) are to be construed to cover both the singular and the plural, unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the disclosed and claimed subject matter and does not pose a limitation on the scope thereof unless otherwise claimed. No language in the specification should be construed as indicating any non-claimed element as essential to the practice of the disclosed and claimed subject matter.

Preferred embodiments of disclosed and claimed subject matter are described herein, including the best mode known to the inventors for carrying out the disclosed and claimed subject matter. Variations of those preferred embodiments may become apparent to those of ordinary skill in the art upon reading the foregoing description. The inventors expect skilled artisans to employ such variations as appropriate, and the inventors intend for the disclosed and claimed subject matter to be practiced otherwise than as specifically described herein. Accordingly, this disclosed and claimed subject matter includes all modifications and equivalents of the subject matter recited in the claims appended hereto as permitted by applicable law. Moreover, any combination of the above-described elements in all possible variations thereof is encompassed by the disclosed and claimed subject matter unless otherwise indicated herein or otherwise clearly contradicted by context.

For ease of reference, “microelectronic device” or “semiconductor substrates” correspond to semiconductor wafers, flat panel displays, phase change memory devices, solar panels and other products including solar substrates, photovoltaics, and microelectromechanical systems (MEMS), manufactured for use in microelectronic, integrated circuit, or computer chip applications. It is to be understood that the term “microelectronic device” is not meant to be limiting in any way and includes any substrate that will eventually become a microelectronic device or microelectronic assembly. The microelectronic device or semiconductor substrates may include low-k dielectric material, barrier materials, and metals, such as, Al, Cu, SnAg alloy, W, Ti, TiN, one or more passivation layers, such as polyimide or polybenzoxazole, as well as Si and other materials thereon.

As defined herein, “low-k dielectric material” corresponds to any material used as a dielectric material in a layered microelectronic device, wherein the material has a dielectric constant less than about 3.5. Preferably, the low-k dielectric materials include low-polarity materials such as silicon-containing organic polymers, silicon-containing hybrid organic/inorganic materials, organosilicate glass (OSG), TEOS, fluorinated silicate glass (FSG), silicon dioxide, and carbon-doped oxide (CDO) glass. It is to be appreciated that the low-k dielectric materials may have varying densities and varying porosities.

As defined herein, the term “barrier material” corresponds to any material used in the art to seal the metal lines, e.g., copper interconnects, to minimize the diffusion of said metal, e.g., copper, into the dielectric material. Preferred barrier layer materials include tantalum, titanium, titanium tungsten, ruthenium, hafnium, and other refractory metals and their nitrides and silicides.

“Substantially free” is defined herein as less than approximately 1 wt. %, more preferably less than approximately 0.5 wt. %, and most preferably less than approximately 0.2 wt. %. “Substantially free” also includes approximately 0.0 wt. %. The term “free of” means 0.0 wt. %. In some embodiments, when describing a composition that is substantially free of water, it is intended to mean that water may be added with the components as impurities; however, the amount of water added with the components should be less than approximately 0.1 wt %; however, water may be absorbed from the atmosphere during manufacturing and use. In other embodiments, substantially free of water may refer to compositions for which the water is not present above approximately 1 wt %. In other embodiments, substantially free of water may refer to compositions for which the water is not present above approximately 3 wt %. In other embodiments, water might be added as part of the raw material and the water level might be present above 2 wt % but less than 5%

The term “about” or “approximately,” when used in connection with a measurable numerical variable, refers to the indicated value of the variable and to all values of the variable that are within the experimental error of the indicated value (e.g., within the 95% confidence limit for the mean) or within percentage of the indicated value (e.g., ±10%, ±5%), whichever is greater.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed. Note all defined weight percent of the components unless otherwise indicated are based on the total weight of the composition. Further, all weight percent unless otherwise indicated are “neat” meaning that they do not include the aqueous solution in which they are present when added to the composition. Any reference to “at least one” could be substituted with “one or more.” “At least one” and/or “one or more” includes “at least two” or “two or more” and “at least three” and “three or more” and so on.

The compositions include inorganic base; two or more organic solvents; one or more corrosion inhibitors and optionally one or more secondary solvents.

In a further embodiment, the composition consists essentially of (i) inorganic hydroxide, (ii) two or more glycol ether, ether alcohol solvents or aromatic containing alcohols and (iii) one or more corrosion inhibitors in varying concentrations and optionally (iv) one or more polyol secondary solvent. In such an embodiment, the combined amounts of (i), (ii), (iii) and (iv) do not equal 100% by weight, and can include other ingredients (e.g., additional solvent(s), including water, common additives and/or impurities) that do not materially change the effectiveness of the cleaning composition.

In another embodiment, the composition consists of (i) inorganic hydroxide, (ii) two or more ether alcohol solvents or aromatic containing alcohols and (iii) one or more corrosion inhibitors in varying concentrations. In such an embodiment, the combined amounts of (i), (ii) and (iii) equal approximately 100% by weight but may include other small and/or trace amounts of impurities that are present in such small quantities that they do not materially change the effectiveness of the composition. For example, in one such embodiment, the cleaning composition can contain 2% by weight or less of impurities. In another embodiment, the cleaning composition can contain 1% by weight or less than of impurities. In a further embodiment, the cleaning composition can contain 0.05% by weight or less than of impurities.

When referring to compositions of the inventive composition described herein in terms of weight %, it is understood that in no event shall the weight % of all components, including non-essential components, such as impurities, add to more than 100 weight %. In compositions “consisting essentially of” recited components, such components may add up to 100 weight % of the composition or may add up to less than 100 weight %. Where the components add up to less than 100 weight %, such composition may include some small amounts of a non-essential contaminants or impurities. For example, in one such embodiment, the composition can contain 2% by weight or less of impurities. In another embodiment, the rinse can contain 1% by weight or less than of impurities. In a further embodiment, the composition can contain 0.05% by weight or less than of impurities. In other such embodiments, the ingredients can form at least 90 wt %, more preferably at least 95 wt %, more preferably at least 99 wt %, more preferably at least 99.5 wt %, most preferably at least 99.8 wt %, and can include other ingredients that do not affect the performance of the cleaning solution. Otherwise, if no significant non-essential impurity component is present, it is understood that the composition of all essential constituent components will essentially add up to 100 weight %.

### DETAILED DESCRIPTION

It is to be understood that both the foregoing general description and the following detailed description are illustrative and explanatory, and are not restrictive of the subject matter, as claimed. The objects, features, advantages and ideas of the disclosed subject matter will be apparent to those skilled in the art from the description provided in the specification, and the disclosed subject matter will be readily practicable by those skilled in the art on the basis of the description appearing herein. The description of any “preferred embodiments” and/or the examples which show preferred modes for practicing the disclosed subject matter are included for the purpose of explanation and are not intended to limit the scope of the claims.

It will also be apparent to those skilled in the art that various modifications may be made in how the disclosed subject matter is practiced based on described aspects in the specification without departing from the spirit and scope of the disclosed subject matter disclosed herein.

As set forth above, the disclosed subject matter relates to photoresist stripper solutions that include, consist essentially of or consist of:
(i) one or more inorganic bases;
(ii) two or more organic solvents where (a) the first solvent is selected from a glycol ether solvent, an ether alcohol solvent and an aromatic ring-containing alcohol and combinations thereof and (b) the second solvent is a polyol solvent; and
(iii) one or more corrosion inhibitors.

In a further aspect, the solutions further optionally include, consist essentially of or consist of (iv) one or more secondary solvent(s).

In solutions that include or consist essentially of the recited ingredients, the total wt % of components (i), (ii), (iii) or (i), (ii), (iii) and (iv) is equal to or less than 100 wt %. In solutions that consist of the recited ingredients, the total wt % of components (i), (ii), (iii) or (i), (ii), (iii) and (iv) is equal to 100 wt %.

In one exemplary embodiment, the photoresist stripper solution includes:
(i) about 0.5 wt % to about 5 wt % of one or more neat inorganic base;
(ii) about 90 wt % to about 97 wt % of two or more organic solvents that are different from one another comprising (a) a first solvent that comprises one or more of a glycol ether solvent, an ether alcohol solvent and an aromatic ring-containing alcohol solvent or mixtures thereof and (b) a second solvent that comprises one or more polyol solvent;
(iii) about 0.01 wt % to about 2 wt % of one or more corrosion inhibitors; and
(iv) optionally one or more secondary solvent(s),
wherein the total wt % of components (i), (ii), (iii) and (iv) is equal to or less than 100 wt %. In a further aspect of this embodiment, the one or more neat inorganic base includes KOH.

In one exemplary embodiment, the photoresist stripper solution includes:
(i) about 1.0 wt % to about 2.5 wt % of one or more neat inorganic base;
(ii) about 90 wt % to about 97 wt % of two or more organic solvents that are different from one another comprising (a) a first solvent that comprises one or more of a glycol ether solvent, an ether alcohol solvent and an aromatic ring-containing alcohol solvent or mixtures thereof and (b) a second solvent that comprises one or more polyol solvent;
(iii) about 0.01 wt % to about 2 wt % of one or more corrosion inhibitors; and
(iv) optionally one or more secondary solvent(s),
wherein the total wt % of components (i), (ii), (iii) and (iv) is equal to or less than 100 wt %. In a further aspect of this embodiment, the one or more neat inorganic base includes KOH.

In one exemplary embodiment, the photoresist stripper solution consists essentially of:
(i) about 0.5 wt % to about 5 wt % of one or more neat inorganic base;
(ii) about 90 wt % to about 97 wt % of two or more organic solvents that are different from one another comprising (a) a first solvent that comprises one or more of a glycol ether solvent, an ether alcohol solvent and an aromatic ring-containing alcohol solvent or mixtures thereof and (b) a second solvent that comprises one or more polyol solvent;
(iii) about 0.01 wt % to about 2 wt % of one or more corrosion inhibitors; and
(iv) optionally one or more secondary solvent(s),
wherein the total wt % of components (i), (ii), (iii) and (iv) is equal to or less than 100 wt %. In a further aspect of this embodiment, the one or more neat inorganic base includes KOH.

In one exemplary embodiment, the photoresist stripper solution consists essentially of:
(i) about 1.0 wt % to about 2.5 wt % of one or more neat inorganic base;
(ii) about 90 wt % to about 97 wt % of two or more organic solvents that are different from one another comprising (a) a first solvent that comprises one or more of a glycol ether solvent, an ether alcohol solvent and an aromatic ring-containing alcohol solvent or mixtures thereof and (b) a second solvent that comprises one or more polyol solvent;
(iii) about 0.01 wt % to about 2 wt % of one or more corrosion inhibitors; and
(iv) optionally one or more secondary solvent(s),
wherein the total wt % of components (i), (ii), (iii) and (iv) is equal to or less than 100 wt %. In a further aspect of this embodiment, the one or more neat inorganic base includes KOH.

In one exemplary embodiment, the photoresist stripper solution consists of:
(i) about 0.5 wt % to about 5 wt % of one or more neat inorganic base;
(ii) about 90 wt % to about 97 wt % of two or more organic solvents that are different from one another comprising (a) a first solvent that comprises one or more of a glycol ether solvent, an ether alcohol solvent and an aromatic ring-containing alcohol solvent or mixtures thereof and (b) a second solvent that comprises one or more polyol solvent;
(iii) about 0.01 wt % to about 2 wt % of one or more corrosion inhibitors; and
(iv) optionally one or more secondary solvent(s),
wherein the total wt % of components (i), (ii), (iii) and (iv) is equal to 100 wt %. In a further aspect of this embodiment, the one or more neat inorganic base includes KOH.

In one exemplary embodiment, the photoresist stripper solution consists of:
(i) about 1.0 wt % to about 2.5 wt % of one or more neat inorganic base;
(ii) about 90 wt % to about 97 wt % of two or more organic solvents that are different from one another comprising (a) a first solvent that comprises one or more of a glycol ether solvent, an ether alcohol solvent and an aromatic ring-containing alcohol solvent or mixtures thereof and (b) a second solvent that comprises one or more polyol solvent;
(iii) about 0.01 wt % to about 2 wt % of one or more corrosion inhibitors; and
(iv) optionally one or more secondary solvent(s),
wherein the total wt % of components (i), (ii), (iii) and (iv) is equal to 100 wt %. In a further aspect of this embodiment, the one or more neat inorganic base includes KOH.

Among other things, the photoresist stripper solutions can be used to remove polymeric resist materials present in a single layer or certain types of bilayer resists. For example, bilayer resists typically have either a first inorganic layer covered by a second polymeric layer or can have two polymeric layers.

### Photoresist Stripper Solution Ingredients

### (i) Inorganic Bases

As noted above, the solutions of the disclosed and claimed subject matter include one or more inorganic bases. Preferably, the one or more inorganic bases include at least one alkali metal hydroxide or a mixture of different alkali metal hydroxides. Suitable inorganic bases include, but are not limited to sodium hydroxide, potassium hydroxide, lithium hydroxide, rubidium hydroxide and cesium hydroxide. In some embodiments, potassium hydroxide is preferentially included. In such embodiments, the potassium hydroxide is used as an aqueous solution, for example a 48 wt % aqueous solution. In other such embodiments, the potassium hydroxide is used as a solid, for example an 85 wt % or 90 wt % flake.

The metal hydroxide may be present in any neat amounts ranging from about 0.1% to about 5%, or from about 0.1 wt % to about 4 wt %, or from about 0.9 wt % to about 4 wt % or from about 0.1 wt % to about 0.8 wt %, or from about 0.4 wt % to about 0.5 wt %, or from about 0.1 wt % to about 0.2 wt % by weight based on the total weight of the composition. More preferably, the metal hydroxide is present, but in an amount not greater than 3.5 wt % by weight. In certain preferred compositions, the metal hydroxide is present at about 1.0 wt % to 2.5 wt % by weight. In certain preferred compositions, the metal hydroxide is present at about 1.5 wt % to 2.25 wt % by weight.

In one embodiment, the solutions include about 1.0 wt % to about 2.5 wt % of neat KOH. In a further aspect of this embodiment, the solutions include about 1.75 wt % to about 2.25 wt % of neat KOH. In another aspect of this embodiment, the solutions include about 1.75 wt % to about 2.1 wt % of neat KOH. In another aspect of this embodiment, the solutions include about 1.75 wt % to about 2.05 wt % of neat KOH. In another aspect of this embodiment, the solutions include about 1.75 wt % to about 2.0 wt % of neat KOH. In another aspect of this embodiment, the solutions include about 1 wt % of neat KOH. In another aspect of this embodiment, the solutions include about 1.25 wt % of neat KOH. In another aspect of this embodiment, the solutions include about 1.5 wt % of neat KOH. In another aspect of this embodiment, the solutions include about 1.75 wt % of neat KOH. In another aspect of this embodiment, the solutions include about 1.8 wt % of neat KOH. In another aspect of this embodiment, the solutions include about 1.9 wt % of neat KOH. In another aspect of this embodiment, the solutions include about 2.0 wt % of neat KOH. In another aspect of this embodiment, the solutions include about 2.05 wt % of neat KOH. In another aspect of this embodiment, the solutions include about 2.1 wt % of neat KOH. In another aspect of this embodiment, the solutions include about 2.15 wt % of neat KOH. In another aspect of this embodiment, the solutions include about 2.2 wt % of neat KOH. In another aspect of this embodiment, the solutions include about 2.25 wt % of neat KOH. In another aspect of this embodiment, the solutions include about 2.3 wt % of neat KOH.

In one embodiment, the solutions include about 1.0 wt % to about 2.5 wt % of neat NaOH. In a further aspect of this embodiment, the solutions include about 1.75 wt % to about 2.25 wt % of neat NaOH. In another aspect of this embodiment, the solutions include about 1.75 wt % to about 2.1 wt % of neat NaOH. In another aspect of this embodiment, the solutions include about 1.75 wt % to about 2.05 wt % of NaOH. In another aspect of this embodiment, the solutions include about 1.75 wt % to about 2.0 wt % of neat NaOH. In another aspect of this embodiment, the solutions include about 1 wt % of neat NaOH. In another aspect of this embodiment, the solutions include about 1.25 wt % of neat NaOH. In another aspect of this embodiment, the solutions include about 1.5 wt % of neat NaOH. In another aspect of this embodiment, the solutions include about 1.75 wt % of neat NaOH. In another aspect of this embodiment, the solutions include about 1.8 wt % of neat NaOH. In another aspect of this embodiment, the solutions include about 1.9 wt % of neat NaOH. In another aspect of this embodiment, the solutions include about 2.0 wt % of neat NaOH. In another aspect of this embodiment, the solutions include about 2.05 wt % of neat NaOH. In another aspect of this embodiment, the solutions include about 2.1 wt % of neat NaOH. In another aspect of this embodiment, the solutions include about 2.15 wt % of neat NaOH. In another aspect of this embodiment, the solutions include about 2.2 wt % of neat NaOH. In another aspect of this embodiment, the solutions include about 2.25 wt % of neat NaOH. In another aspect of this embodiment, the solutions include about 2.3 wt % of neat NaOH.

### (ii) Organic Solvents

The solutions of the disclosed and claimed subject matter include two or more organic solvents (i.e., a first solvent and a second solvent) where (a) the first solvent is selected from a glycol ether solvent, an ether alcohol solvent and an aromatic ring-containing alcohol and combinations thereof and (b) the second solvent is a polyol solvent. The two solvents are different from one another.

In one embodiment, the solutions include about 90 wt % to about 97 wt % of the two or more organic solvents. In a further aspect of this embodiment, the solutions include about 94 wt % to about 97 wt % of the two or more organic solvents. In a further aspect of this embodiment, the two or more organic solvents include (a) about 60 wt % to about 80 wt % of a first solvent that and (b) about 10 wt % to about 30 wt % of a second solvent. In a further aspect of this embodiment, the two or more organic solvents include (a) about 68 wt % to about 77 wt % of a first solvent that and (b) about 11 wt % to about 28 wt % of a second solvent.

### First Solvent

In some embodiments, the first solvent is selected from an ether alcohol, an aromatic ring-containing alcohol solvent, or a mixture thereof. One type of ether alcohol solvent may be a glycol ether. Suitable glycol ether solvents include, but are not limited to, diethylene glycol butyl ether (DB), diethylene glycol methyl ether, diethylene glycol ethyl ether, diethylene glycol propyl ether, propylene glycol methyl ether, dipropylene glycol methyl ether, propylene glycol propyl ether, dipropylene glycol propyl ether, propylene glycol phenyl ether, propylene glycol n-butyl ether, dipropylene glycol n-butyl ether, ethylene glycol propyl ether, ethylene glycol butyl ether, ethylene glycol phenyl ether, tripropylene glycol methyl ether, dipropylene glycol dimethyl ether, diethylene glycol methyl ethyl ether, diethylene glycol dimethyl ether, diethylene glycol diethyl ether, triethylene glycol monomethyl ether (TEGME), triethylene glycol monoethyl ether, triethylene glycol monopropyl ether and triethylene glycol monobutyl ether. Other suitable types of ether alcohol solvents that are not glycol ethers (i.e., other alcohols having an ether group). Examples are 3-methoxy-3-methyl-1-butanol (MMB), furfuryl alcohol, tetrahydrofurfuryl alcohol.

Suitable aromatic ring-containing alcohol solvents include substituted benzene, such as, benzyl alcohol, benzyl ethanol and benzyl propanol.

In one embodiment, the first solvent includes triethylene glycol monomethyl ether (TEGME). In a further aspect of this embodiment, the first solvent is about 60 wt % to about 80 wt % of triethylene glycol monomethyl ether (TEGME). In a further aspect of this embodiment, the first solvent is about 68 wt % to about 77 wt % of triethylene glycol monomethyl ether (TEGME).

### Second Solvent

As noted above, the second solvent is different from the first solvent and is a polyol solvent. In some embodiments, the second solvent includes one or more of, but are not limited to, ethylene glycol (EG), diethylene glycol (DEG), triethylene glycol (TEG), dipropylene glycol, glycerol and propylene glycol (PG). In a further aspect of this embodiment, the second solvent includes about 10 wt % to about 30 wt % of ethylene glycol (EG), diethylene glycol (DEG), triethylene glycol (TEG), dipropylene glycol, glycerol and propylene glycol (PG). In a further aspect of this embodiment, the second solvent includes about 10 wt % to about 30 wt % of diethylene glycol (DEG) and propylene glycol (PG). In a further aspect of this embodiment, the second solvent includes about 11 wt % to about 28 wt % of diethylene glycol (DEG) and propylene glycol (PG).

In one embodiment, the two or more organic solvents include (a) a first solvent that includes about 60 wt % to about 80 wt % of one or more of an ether alcohol, an aromatic ring-containing alcohol solvent or mixtures thereof and (b) a second solvent that includes about 10 wt % to about 30 wt % of one or more of a polyol solvent. In a further aspect of this embodiment, the two or more organic solvents include (a) a first solvent that includes about 68 wt % to about 77 wt % of one or more of an ether alcohol, an aromatic ring-containing alcohol solvent or mixtures thereof and (b) a second solvent that includes about 11 wt % to about 28 wt % of one or more of a polyol solvent.

In one embodiment, the two or more organic solvents include (a) a first solvent that includes about 60 wt % to about 80 wt % of triethylene glycol monomethyl ether (TEGME) and (b) a second solvent that includes about 10 wt % to about 30 wt % of one or more of polyol solvent.

In one embodiment, the two or more organic solvents include (a) about 60 wt % to about 80 wt % a first solvent that is one or more of an ether alcohol, an aromatic ring-containing alcohol or mixtures thereof and (b) about 10 wt % to about 30 wt % a second solvent that is one or more of ethylene glycol (EG), diethylene glycol (DEG), triethylene glycol (TEG), glycerol, propylene glycol (PG) and mixtures thereof.

In one embodiment, the two or more organic solvents include (a) a first solvent that includes about 68 wt % to about 77 wt % of triethylene glycol monomethyl ether (TEGME) and (b) a second solvent that includes about 11 wt % to about 28 wt % of ethylene glycol (EG), diethylene glycol (DEG), triethylene glycol (TEG), glycerol, propylene glycol (PG) and mixtures thereof. In a further aspect of this embodiment, the two or more organic solvents include (a) a first solvent that includes about 68 wt % to about 77 wt % of triethylene glycol monomethyl ether (TEGME) and (b) a second solvent that includes about 11 wt % to about 28 wt % of diethylene glycol (DEG) and propylene glycol (PG)

In other embodiments, the two or more organic solvents include from about 50% to about 90%, or 55% to about 90% by wt. of the composition. Other embodiments of the disclosed and claimed subject matter include from about 60% to about 88%, or 65% to 85% by wt. of the glycol ether solvent and/or aromatic containing alcohol. The two or more organic solvents can individually or collectively fall within a range defined by the following list of weight percents: 50, 55, 58, 60, 62, 65, 67, 70, 72, 75, 77, 80, 82, 85, 88 and 90.

In some embodiments, the solutions are free or essentially free of an amide-containing solvent. By essentially free it is meant an amount less than 1 percent, alternately less than 0.1 weight percent, alternately less than 0.01 weight percent, or less than 0.001 weight percent, or free of, where free of is non-detectable or 0.

In other embodiments, the solutions may be free or essentially free of a sulfur containing solvent. In a further aspect of this embodiment, the compositions are free or essentially free of dimethyl sulfoxide (DMSO) and n-methyl-2-pyrrolidone (NMP). By essentially free it is meant an amount less than 1 percent, alternately less than 0.1 weight percent, alternately less than 0.01 weight percent, or less than 0.001 weight percent, or free of, where free of is non-detectable or 0.

(iii) Corrosion Inhibitors

The solutions of the disclosed and claimed subject matter include one or more corrosion inhibitors. Suitable corrosion inhibitors include, but are not limited to, organic corrosion inhibitors, including aromatic hydroxyl compounds, and aromatic polyhydroxyl compounds such as catechol and resorcinol; alkylcatechols, such as methylcatechol, ethylcatechol and t-butylcatechol, phenols and pyrogallol; aromatic triazoles such as benzotriazole; alkylbenzotriazoles and aminobenzotriazoles, such as, 1-aminobenzotriazole; thiazoles, such as, 2-aminobenzothiazole (ABT); sugar alcohols such as glycerol, xylitol and sorbitol; metal salts such as copper (II) nitrate; copper (II) bromide; copper (II) chlorate; copper (II) chloride; copper (II) fluorosilicate; copper (II) formate; copper (II) selenate; copper (II) sulfate; carboxylic acids, such as sebacic acid, formic acid, acetic acid, propionic acid, butyric acid, isobutyric acid, oxalic acid, malonic acid, succinic acid, glutaric acid, maleic acid, fumaric acid, benzoic acid, phtahlic acid, 1,2,3-benzenetricarboxylic acid, glycolic acid, lactic acid, malic acid, citric acid, acetic anhydride, phthalic anhydride, maleic anhydride, succinic anhydride, salicylic acid, gallic acid, and gallic acid esters such as methyl gallate and propyl gallate; organic salts of carboxyl containing organic containing compounds described above, and the like, and chelate compounds such as phosphoric acid-based chelate compounds including 1,2-propanediaminetetramethylene phosphonic acid and hydroxyethane phosphonic acid, carboxylic acid-based chelate compounds such as ethylenediaminetetraacetic acid and its sodium and ammonium salts, dihydroxyethylglycine and nitrilotriacetic acid, amine-based chelate compounds such as bipyridine, tetraphenylporphyrin and phenanthroline, and oxime-based chelate compounds such as dimethylglyoxime and diphenylglyoxime. In other embodiments, the one or more corrosion inhibitors may include one or more copper salts, such as, copper (II) nitrate; copper (II) bromide; copper (II) chlorate; copper (II) chloride; copper (II) fluorosilicate; copper (II) formate; copper (II) selenate; and/or copper (II) sulfate alone. In yet other embodiments, the compositions may include one or more of the organic corrosion inhibitors and/or chelate compounds above and one or more copper salts. In yet other embodiments, the one or more corrosion inhibitors may be copper (II) nitrate (e.g., NADA/1N is about 26.3% copper (II) nitrate hemi(pentahydrate-non-oxidizer)), copper (II) bromide; copper (II) chlorate; copper (II) chloride; copper (II) fluorosilicate; copper (II) formate; copper (II) selenate; copper (II) sulfate and/or resorcinol. In yet another embodiment the corrosion inhibitor may include copper (II) nitrate and resorcinol.

In other embodiments the corrosion inhibitor can include aliphatic or aromatic polyhydroxyl compounds which include, ethylene glycol; 1,2-propanediol (propylene glycol); 1,3-propanediol, 1,2,3-propanetriol; 1,2-butanediol; 1,3-propanediol; 2,3-butanediol; 1,4-butanediol; 1,2,3-butanetriol; 1,2,4-butanetriol; 1,2-pentanediol; 1,3-pentanediol; 1,4-pentandiol; 2,3-pentanediol; 2,4-pentandiol; 3,4-pentanediol; 1,2,3-pentanetriol; 1,2,4-pentanetriol; 1,2,5-pentanetriol; 1,3,5-pentanetriol; etohexadiol; p-methane-3,8-polyhydroxyl compound; 2-methyl-2,4-pentanediol; 2,2-dimethyl-1,3-propanediol; glycerin; trirnethylolpropane; xylitol; arabitol; 1,2- or 1,3-cyclopentanediol; 1,2- or 1,3-cyclohexanediol; 2,3-norbornanediol; 1,8-octanediol; 1,2-cyclohexane-dimethanol; 1,3-cyclohexanedimethanol; 1,4-cyclohexanedimethanol; 2,2,4-trimethyl-1,3-pentanediol; hydroxypivalyl hydroxypivalate; 2-methyl-1,3-propanediol; 2-butyl-2-ethyl-1,3-propanediol; 2-ethyl-2-isobutyl-1,3-propanediol; 1,6-hexanediol; 2,2,4,4-tetramethyl-1,6-hexanediol; 1,10-decanediol; 1,4-benzenedimethanol; hydrogenated bisphenol A; 1,1,1-trimethylol propane; 1,1,1-trimethylolethane; pentaerythritol; erythritol; threitol; dipentaerythritol; sorbitol, mannitol, resorcinol, catechol and the like, and combinations of 2 or more of the aforementioned polyhydroxyl compounds.

In some embodiments one or more organic corrosion inhibitors is present in the solutions at levels ranging from about 0.005 wt % to about 10 wt %. In one embodiment, the solution may contain about 0.25 weight percent to about 5 weight percent or 0.1 weight percent to about 4 weight percent or 0.25 weight percent to about 2 weight percent. The one or more corrosion inhibitors may be present in any amount defined by the endpoints selected from the following weight percents: 0.005, 0.02, 0.08, 0.1, 0.2, 0.25, 0.3, 0.4, 0.5, 0.7, 0.9, 1, 2, 3, 4, 5, 6, 7, 8, 9 and 10. A first and second corrosion inhibitor may be used in the composition. This disclosed and claimed subject matter includes the method of treating semiconductor substrates with the compositions to remove photoresist without damaging the films, layers, metals or other structures present on the substrates, including passivation layers, such as PI and PBO. Preferred temperatures for treating the semiconductor substrates are about 70° C. For a majority of applications, temperatures of from about 45° C. to about 90° C. are useful or from about 50° C. to about 75° C. For particular applications where the substrate is either sensitive or longer removal times are required, lower contacting temperatures are appropriate. For example, when reworking substrates, it may be appropriate to maintain the stripper solution at a temperature of at least 20° C. for a longer time to remove the photoresist and avoid damaging to the substrate.

In some embodiments, the one or more corrosion inhibitors includes one or more of BZT, sorbitol, resorcinol, sebacic acid, glycerol and copper (II) nitrate. In some embodiments, these corrosion inhibitors are present (alone or in combination) between about 0.01 wt % and about 2 wt %. In some embodiments, these corrosion inhibitors are present (alone or in combination) between about 0.2 wt % and about 1 wt %. In some embodiments, these corrosion inhibitors are present (alone or in combination) at about 0.5 wt %.

In some embodiments, the one or more corrosion inhibitors includes BZT. In one aspect of this embodiment, the solution includes about 0.5 wt % to about 1 wt % of BZT. In another aspect of this embodiment, the solution includes about 0.5 wt % of BZT. In another aspect of this embodiment, the solution includes about 1.0 wt % of BZT.

In some embodiments, the one or more corrosion inhibitors includes sorbitol. In one aspect of this embodiment, the solution includes about 0.2 wt % to about 1 wt % of sorbitol. In another aspect of this embodiment, the solution includes about 0.2 wt % of sorbitol. In another aspect of this embodiment, the solution includes about 0.5 wt % of sorbitol. In another aspect of this embodiment, the solution includes about 1.0 wt % of sorbitol.

In some embodiments, the one or more corrosion inhibitors includes resorcinol. In one aspect of this embodiment, the solution includes about 0.2 wt % to about 1 wt % of resorcinol. In another aspect of this embodiment, the solution includes about 0.2 wt % of resorcinol. In another aspect of this embodiment, the solution includes about 0.5 wt % of resorcinol. In another aspect of this embodiment, the solution includes about 1.0 wt % of resorcinol.

In some embodiments, the one or more corrosion inhibitors includes glycerol. In one aspect of this embodiment, the solution includes about 0.2 wt % to about 1 wt % of glycerol. In another aspect of this embodiment, the solution includes about 0.2 wt % of glycerol. In another aspect of this embodiment, the solution includes about 0.5 wt % of glycerol. In another aspect of this embodiment, the solution includes about 1.0 wt % of glycerol.

In some embodiments, the one or more corrosion inhibitors includes sebacic acid. In one aspect of this embodiment, the solution includes about 0.2 wt % to about 1 wt % of sebacic acid. In another aspect of this embodiment, the solution includes about 0.2 wt % of sebacic acid. In another aspect of this embodiment, the solution includes about 0.5 wt % of sebacic acid. In another aspect of this embodiment, the solution includes about 1.0 wt % of sebacic acid.

In some embodiments, the one or more corrosion inhibitors includes copper nitrate. In one aspect of this embodiment, the solution includes about 0.005 wt % to about 0.5 wt % of copper nitrate. In another aspect of this embodiment, the solution includes about 0.01 wt % of copper nitrate. In another aspect of this embodiment, the solution includes about 0.2 wt % of copper nitrate. In another aspect of this embodiment, the solution includes about 0.5 wt % of copper nitrate.

### (iv) Secondary Solvents (Optional)

Some embodiments may contain a secondary solvent in addition to the solvents described above. Alternatively, in some embodiments, the stripper solutions may be free or substantially free of a secondary solvent.

In some embodiments, the secondary solvent includes one of water or an alcohol containing one hydroxyl group.

Secondary organic solvent alcohols may be linear or branched chain aliphatic or aromatic alcohols. Examples of the secondary alcohols include methanol, ethanol, propanol, isopropyl alcohol, butanol, tert-butyl alcohol, tert-amyl alcohol, 3-methyl-3-pentanol, 1-octanol, 1-decanol, 1-undecanol, 1-dodecanol, 1-tridecanol, 1-tetradecanol, 1-pentadecanol, 1-hexadecanol, 9-hexadecen-1-ol, 1-heptadecanol, 1-octadecanol, 1-nonadecanol, 1-eicosanol, 1-heneicosanol, 1-docosanol, 13-docosen-1-ol, 1-tetracosanol, 1-hexacosanol, 1-heptacosanol, 1-octacosanol, 1-triacontanol, 1-dotriacontanol, 1-tetratriacontanol and cetearyl alcohol.

When used, the secondary organic solvent may include from about 0.02% to about 50%, or from about 0.08% to about 38%, or from about 0.1% to about 35%, or from about 0.2% to about 33%, or from about 0.3% to about 20%, or from about 1% to about 15% of the composition. In alternative embodiments the secondary solvent may be present in any amount defined by the endpoints selected from the following weight percents: 0.02, 0.08, 0.1, 0.2, 0.3, 0.4, 0.5, 0.7, 0.9, 1, 3, 5, 8, 10, 12, 15, 17, 20, 23, 25, 28, 30, 32, 35, 37, 40, 43, 45, 47 and 50.

### Other Optional or Excluded Ingredients

In some embodiments, the disclosed and claimed solutions are substantially free of, alternatively free of (as those terms were defined earlier) one or more than one of the following in any combination: nitrogen containing solvents, bis-choline salts, tri-choline salts, oxoammonium compounds, hydroxylamines and derivatives thereof, hydrogen peroxide, oxidants, surfactants, and combinations thereof.

In some embodiments, the compositions disclosed herein are formulated to be substantially free or free of at least one of the following chemical compounds: alkyl thiols, and organic silanes.

In some embodiments, the disclosed and claimed solutions are formulated to be substantially free or free of one or more of the following: halide-containing compound, for example it may be substantially free or free of one or more of the following: fluoride-, bromine-, chlorine- or iodine-containing compounds.

In some embodiments, the disclosed and claimed solutions are substantially free or free of sulfonic acid and/or phosphoric acid and/or sulfuric acid and/or nitric acid and/or hydrochloric acid.

In some embodiments, the disclosed and claimed solutions are substantially free or free of: ethyl diamine, sodium-containing compounds and/or calcium-containing compounds and/or manganese-containing compounds or magnesium-containing compounds and/or chromium-containing compounds and/or sulfur-containing compounds and/or silane-containing compounds and/or phosphorus-containing compounds.

In some embodiments, the disclosed and claimed solutions are substantially free of or free of surfactants.

In some embodiments, the disclosed and claimed solutions are substantially free or free of amphoteric salts, and/or cationic surfactants, and/or anionic surfactants, and/or zwitterionic surfactants, and/or non-ionic surfactants.

In some embodiments, the disclosed and claimed solutions are free of or free of imidizoles, and/or anhydrides.

In some embodiments, the disclosed and claimed solutions are substantially free of or free of pyrrolidones, and/or acetamides.

In some embodiments, the disclosed and claimed solutions are substantially free or free of any amines and alkanolamines.

In some embodiments, the disclosed and claimed solutions are substantially free of or free of peroxy-compounds, and/or peroxides, and/or persulfates, and/or percarbonates, and acids thereof, and salts thereof.

In some embodiments, the disclosed and claimed solutions are substantially free of or free of iodates, and/or perboric acid, and/or percarbonates, and/or peroxyacids, and/or cerium compounds, and/or cyanides, and/or periodic acid and/or ammonium molybdate, and/or ammonia and/or abrasives.

### Methods of Use

The disclosed and claimed subject matter further includes a method of removing, in whole or on part, one or more photoresists or similar materials from a substrate using one or of the disclosed and claims photoresist stripper solutions. As noted above, the disclosed and claimed photoresist stripper solutions can be used to remove polymeric resist materials present in a single layer or certain types of bilayer resists. Utilizing the methods taught below, a single layer of polymeric resist can be effectively removed from a standard wafer having a single polymer layer. The same methods can also be used to remove a single polymer layer from a wafer having a bilayer composed of a first inorganic layer and a second or outer polymer layer. Finally, two polymer layers can be effectively removed from a wafer having a bilayer composed of two polymeric layers.

In one aspect of this embodiment, the process or method for removing a photoresist or similar material from a substrate includes the steps of:
(i) contacting the substrate with one or more of the photoresist stripper solutions for a time sufficient to remove a desired amount of the photoresist or similar material,
(ii) removing the substrate from the stripping solution,
(iii) rinsing the stripping solution from the substrate with DI water or a solvent, and
(iv) optionally drying the substrate.

In one embodiment, step (i) includes immersing the substrate one or more of the photoresist stripper solutions and optionally agitating the substrate to facilitate photoresist removal. Such agitation can be affected by mechanical stirring, circulating or by bubbling an inert gas through the composition.

In one embodiment, step (ii) includes rinsing the substrate rinsed with water or an alcohol. In one aspect of this embodiment, DI water is a preferred form of water. In another aspect of this embodiment, isopropanol (IPA) is a preferred solvent. In another aspect of this embodiment, components subject to oxidation are or can be rinsed under an inert atmosphere.

Utilizing the above methods (as well as variants thereof), the disclosed and claimed photoresist stripper solutions can be used for removal of thick and thin positive or negative tone photoresists. Thick photoresists may be a resist of from about 5 μm to about 100 μm or more, or about 15 μm to 100 μm, or from about 20 μm to about 100 μm in advanced packaging applications for semiconductor devices. In other cases, the chemical solutions may be used to remove photoresist from about 1 μm to about 100 μm or more, or about 2 μm to 100 μm, or from about 3 μm to about 100 μm.

### EXAMPLES

Reference will now be made to more specific embodiments of the present disclosure and experimental results that provide support for such embodiments. The examples are given below to more fully illustrate the disclosed subject matter and should not be construed as limiting the disclosed subject matter in any way.

It will be apparent to those skilled in the art that various modifications and variations can be made in the disclosed subject matter and specific examples provided herein without departing from the spirit or scope of the disclosed subject matter. Thus, it is intended that the disclosed subject matter, including the descriptions provided by the following examples, covers the modifications and variations of the disclosed subject matter that come within the scope of any claims and their equivalents.

### Materials and Methods

All materials used in this patent were purchased from and/or are available from Sigma Aldrich and were used in the formulations as received.

Cleaning performance and polyimide (PI) compatibility ware inspected using optical microscope and scanning electron microscope. Cu and Al etch rates are determined by measuring film thickness using four-point probe RESMAP before and after processing in the formulations.

The follow abbreviations are used in the various compositions in the tables below:

| Abbreviation | Full name |
|---|---|
| KOH | Potassium Hydroxide |
| NaOH | Sodium Hydroxide |
| BA | Benzyl Alcohol |
| DB | Diethylene Glycol Monobutyl Ether |
| DE | Diethylene Glycol Monoethyl Ether |
| MMB | 3-Methoxy-3-Methyl-1-Butanol |
| DEG | Diethylene Glycol |
| PG | Propylene Glycol |
| TEGME | Triethylene Glycol Monomethyl Ether |
| BZT | Benzotriazole |
| MEA | Monoethanolamine |

The low temperature cure PI is a polyimide passivation layer (or insulation layer) that is cured at less than approximately 250° C.

In the examples, various stripping compositions (examples and comparative examples) comprising the formulations identified in the tables below were tested for their ability to remove photoresist from semiconductor wafer samples. The coupon-sized samples of semiconductor wafers were silicon wafers plated with Cu pillars and Sn/Ag solder caps having a thick layer of spin-on photoresist thereon. The photoresist removal was performed using an immersion process in a beaker. The photoresist on the test coupons was a negative spin-on photoresist. Other test coupons had a passivation layer of polyimide (PI) on them. Amounts of materials in all of the tables are reported as wt % values and reflect “neat” values where appropriate unless indicated otherwise. The balance of the formulation weights is from water present in the raw materials.

Table 1 lists the results of Cu and Al etch rate, PI compatibility and photoresist removal effectiveness. The test results reported in Table 1 were for photoresist removal from photoresist patterned coupons, and compatibility with separate coupons having PI passivation layer at the process conditions (temperature and time) specified.

TABLE 1
Comparative Example Formulation

| | | | Comparative | Comparative |
|---|---|---|---|---|
| | | | Example 1 | Example 2 |
| KOH | | | 1.8 | 2.03 |
| MMB | | | 20 | — |
| DB | | | 65 | — |
| TEGME | | | — | 70 |
| PG | | | — | 12.75 |
| DEG | | | 5 | 15 |
| MEA | | | 8 | — |
| Cu Nitrate | | | 0.01 | — |
| Total | | | 99.81 | 99.78 |
| Process Temp. | | | 70° C. | 70° C. |
| Cu etch rate/Å/min. | | | <0.5 | 2.91 |
| Al etch rate/Å/min. | | | 115.9 | 3.54 |
| | Negative photoresist | 50 min | Clean | Clean |
| | removal | | | |
| | PI | 90 min | PI attack | No PI attack |
| | (Low Temperature | | | |
| | Cure) | | | |

TABLE 2
Example Formulations

| Ex. | 1 | 2 | 3 | 4 | 5 | 6 | 7 | 8 | 9 | 10 |
|---|---|---|---|---|---|---|---|---|---|---|
| KOH | 2.03 | 2.03 | 2.03 | 2.03 | 2.03 | 2.03 | 2.03 | 1.1 | — | 1.05 |
| NaOH | — | — | — | — | — | — | — | — | 2.05 | 1.0 |
| PG | 12.75 | 12.75 | 12.75 | 12.75 | 12.75 | 12.75 | 12.75 | 12.75 | 12.75 | 12.75 |
| TEGME | 69.5 | 69 | 68.5 | 69.5 | 69.5 | 69.5 | 69.5 | 70.65 | 69.65 | 69.56 |
| DEG | 15 | 15 | 15 | 15 | 15 | 15 | 15 | 15 | 15 | 15 |
| Sorbitol | 0.5 | 0.5 | 0.5 | — | — | 0.5 | — | 0.5 | 0.5 | 0.5 |
| BZT | — | 0.5 | 1 | 0.5 | — | — | — | — | — | — |
| Resorcinol | — | — | — | — | 0.5 | — | — | — | — | — |
| Sebacic Acid | — | — | — | — | — | 0.5 | — | — | — | — |
| Copper Nitrate | — | — | — | — | — | — | 0.01 | — | — | — |
| Total | 99.78 | 99.78 | 99.78 | 99.78 | 99.78 | 99.78 | 99.29 | 99.88 | 99.95 | 99.86 |

TABLE 3
Example Formulations

| Ex. | 11 | 12 | 13 | 14 | 15 | 16 | 17 |
|---|---|---|---|---|---|---|---|
| KOH | 2.03 | 2.03 | 2.03 | 2.03 | 2.03 | 2.03 | 2.03 |
| PG | 12.75 | 12.75 | 12.75 | 12.75 | 12.75 | 12.75 | 12.75 |
| TEGME | — | — | — | — | 40 | 40 | 40 |
| MMB | 69.5 | — | — | — | 29.5 | — | — |
| DB | — | 69.5 | — | — | — | 29.5 | — |
| BA | — | — | 69.5 | — | — | — | 29.5 |
| DE | — | — | — | 69.5 | — | — | — |
| DEG | 15 | 15 | 15 | 15 | 15 | 15 | 15 |
| Sorbitol | 0.5 | 0.5 | 0.5 | 0.5 | 0.5 | 0.5 | 0.5 |
| Total | 99.78 | 99.78 | 99.78 | 99.78 | 99.78 | 99.78 | 99.78 |

### Analysis of Example Formulations

### Analysis 1: Corrosion Inhibitors and Etch Rate

Table 4 and 5 lists (i) comparative stripping solutions and (ii) solutions according to the disclosed and claimed subject matter that were tested using an immersion process to measure Cu and Al etch rate. Testing was performed using blanket Cu or Al wafer. For the immersion process, three coupon-sized samples of semiconductor wafers were processed in beakers. Beakers were filled with 100 grams of a stripping composition and heated to the target temperature. When the stripping composition was at the target temperature, three coupons were placed in a holder in the beaker, and slight agitation was provided by a stir bar. Temperature was maintained at the process temperature in the table throughout the process. After a total processing time of 25 minutes, the coupons were removed from the beaker, rinsed with DI water and IPA, and dried with a stream of nitrogen.

The thickness of the Cu or Al layer was measured before and after processing for each coupon using RESMAP to calculate the change in thickness and the etch rate. In Table 4 and 5, a single corrosion inhibitor or combination of two corrosion inhibitors were studied by monitoring Cu etch rate and aluminum etch rate. All corrosion inhibitors listed in the table 4 and 5 reduced Cu etch to a different degree (formulation 1-17) compared to the one without any corrosion inhibitor (Comp. 2). The solutions of the disclosed and claimed subject matter illustrated in table 4 and 5 significantly lower Al etch rate than the comparative example 1 and 2 except formulation 4-7.

TABLE 4
Corrosion Inhibitor Effect on Cu and Al Etch Rate

| | Comp. | Comp. | | | | | | | | | | |
|---|---|---|---|---|---|---|---|---|---|---|---|---|
| Ex. | 1 | 2 | 1 | 2 | 3 | 4 | 5 | 6 | 7 | 8 | 9 | 10 |
| KOH | 1.8 | 2.03 | 2.03 | 2.03 | 2.03 | 2.03 | 2.03 | 2.03 | 2.03 | 1.1 | — | 1.05 |
| NaOH | — | — | — | — | — | — | — | — | — | — | 2.05 | 1.0 |
| PG | — | 12.75 | 12.75 | 12.75 | 12.75 | 12.75 | 12.75 | 12.75 | 12.75 | 12.75 | 12.75 | 12.75 |
| TEGME | — | 70 | 69.5 | 69 | 68.5 | 69.5 | 69.5 | 69.5 | 69.5 | 70.65 | 69.65 | 69.56 |
| DEG | 5 | 15 | 15 | 15 | 15 | 15 | 15 | 15 | 15 | 15 | 15 | 15 |
| DB | 65 | — | — | — | — | — | — | — | — | — | — | — |
| MMB | 20 | — | — | — | — | — | — | — | — | — | — | — |
| MEA | 8 | — | — | — | — | — | — | — | — | — | — | — |
| Sorbitol | — | — | 0.5 | 0.5 | 0.5 | — | — | — | — | 0.5 | 0.5 | 0.5 |
| BZT | — | — | — | 0.5 | 1 | 0.5 | — | — | — | — | — | — |
| Resorcinol | — | — | — | — | — | — | 0.5 | — | — | — | — | — |
| Sebacic Acid | — | — | — | — | — | — | — | 0.5 | — | — | — | — |
| Copper Nitrate | 0.01 | — | — | — | — | — | — | — | 0.01 | — | — | — |
| Total | 99.81 | 99.78 | 99.78 | 99.78 | 99.78 | 99.78 | 99.78 | 99.78 | 99.29 | 99.88 | 99.95 | 99.86 |
| Temp./° C. | 80 | 70 | 70 | 70 | 70 | 70 | 70 | 70 | 70 | 70 | 70 | 70 |
| Time/min. | 30 | 25 | 25 | 25 | 25 | 25 | 25 | 25 | 25 | 25 | 25 | 25 |
| Cu E/R: Å/min. | <0.5 | 2.91 | <0.5 | <0.5 | <0.5 | 1.29 | <0.5 | 1.51 | <0.5 | <0.5 | <0.5 | <0.5 |
| Al E/R: Å/min. | 115.9 | 3.54 | <0.5 | 1.31 | 0.52 | 3.42 | 5.07 | 2.95 | 3.23 | <0.5 | 1.48 | 0.59 |

TABLE 5
Corrosion Inhibitor Effect on Cu and Al Etch Rate

| Ex. | 11 | 12 | 13 | 14 | 15 | 16 | 17 |
|---|---|---|---|---|---|---|---|
| KOH | 2.03 | 2.03 | 2.03 | 2.03 | 2.03 | 2.03 | 2.03 |
| PG | 12.75 | 12.75 | 12.75 | 12.75 | 12.75 | 12.75 | 12.75 |
| TEGME | — | — | — | — | 40 | 40 | 40 |
| MMB | 69.5 | — | — | — | 29.5 | — | — |
| DB | — | 69.5 | — | — | — | 29.5 | — |
| BA | — | — | 69.5 | — | — | — | 29.5 |
| DE | — | — | — | 69.5 | — | — | — |
| DEG | 15 | 15 | 15 | 15 | 15 | 15 | 15 |
| Sorbitol | 0.5 | 0.5 | 0.5 | 0.5 | 0.5 | 0.5 | 0.5 |
| Total | 99.78 | 99.78 | 99.78 | 99.78 | 99.78 | 99.78 | 99.78 |
| Temp./° C. | 70 | 70 | 70 | 70 | 70 | 70 | 70 |
| Time/min. | 25 | 25 | 25 | 25 | 25 | 25 | 25 |
| Cu E/R: Å/min. | <0.5 | <0.5 | <0.5 | <0.5 | <0.5 | <0.5 | <0.5 |
| Al E/R: Å/min. | <0.5 | 1.88 | <0.5 | <0.5 | 0.58 | <0.5 | <0.5 |

### Analysis 2: Resist Cleaning Performance

Tables 6 lists various (i) comparative stripping solutions and (ii) solutions according to the disclosed and claimed subject matter that were tested using an immersion process and semiconductor wafers with 65 μm thick negative spin-on photoresist with plated Cu pillars and Sn/Ag solder caps. For the immersion process, coupon-sized samples of semiconductor wafers were processed in beakers. Beakers were filled with 100.0 grams of a stripping solution and heated to the target temperature of 80° C. When the stripping solution was at the process temperature, a coupon was placed in a holder in the beaker, and slight agitation was provided by a stir bar. Temperature was maintained at the process temperature while contacting the coupons during the cleaning process. After a set processing, the coupons were removed from the beaker, rinsed with DI water and IPA, and dried with a stream of nitrogen.

Resist removal was defined as “clean” if all of the resist was removed from the wafer coupon surface; as “mostly clean” if at least 95% of the resist was removed from the surface; “partly clean” if about 80% of the resist was removed from the surface. All formulations were able to completely remove positive photoresist at 50 minutes at 80° C. except for example 8, 12 and 16 where the coupon was only mostly clean after 50 minutes.

TABLE 6
Resist Removal Performance

| | Comp. | Comp. | | | | | | | | | | | |
|---|---|---|---|---|---|---|---|---|---|---|---|---|---|
| Ex. | 1 | 2 | 1 | 8 | 9 | 10 | 11 | 12 | 13 | 14 | 15 | 16 | 17 |
| KOH | 1.8 | 2.03 | 2.03 | 1.1 | — | 1.05 | 2.03 | 2.03 | 2.03 | 2.03 | 2.03 | 2.03 | 2.03 |
| NaOH | — | — | — | — | 2.05 | 1.0 | — | — | — | — | — | — | — |
| MEA | 8 | — | — | — | — | — | — | — | — | — | — | — | — |
| PG | — | 12.75 | 12.75 | 12.75 | 12.75 | 12.75 | 12.75 | 12.75 | 12.75 | 12.75 | 12.75 | 12.75 | 12.75 |
| MMB | 20 | — | — | — | — | — | 69.5 | — | — | — | 29.5 | — | — |
| DB | 65 | — | — | — | — | — | — | 69.5 | — | — | — | 29.5 | — |
| BA | — | — | — | — | — | — | — | — | 69.5 | — | — | — | 29.5 |
| DE | — | — | — | — | — | — | — | — | — | 69.5 | — | — | — |
| TEGME | — | 70 | 69.5 | 70.65 | 69.65 | 69.56 | — | — | — | 40 | 40 | 40 | 40 |
| DEG | 5 | 15 | 15 | 15 | 15 | 15 | 15 | 15 | 15 | 15 | 15 | 15 | 15 |
| Cu nitrate | 0.01 | — | — | — | — | — | — | — | — | — | — | — | — |
| Sorbitol | — | — | 0.5 | 0.5 | 0.5 | 0.5 | 0.5 | 0.5 | 0.5 | 0.5 | 0.5 | 0.5 | 0.5 |
| Total | 99.81 | 99.78 | 99.78 | 99.88 | 99.95 | 99.86 | 99.78 | 99.78 | 99.78 | 99.78 | 99.78 | 99.78 | 99.78 |
| Temp./° C. | 80 | 80 | 80 | 80 | 80 | 80 | 80 | 80 | 80 | 80 | 80 | 80 | 80 |
| Time/min | 50 | 50 | 50 | 50 | 50 | 50 | 50 | 50 | 50 | 50 | 50 | 50 | 50 |
| Resist | Clean | Clean | Clean | Mostly | Clean | Clean | Clean | Mostly | Clean | Clean | Clean | Mostly | Clean |
| Removal | | | | clean | | | | clean | | | | clean | |

### Analysis 4: Polyimide Compatibility

Table 7 provides the results for various (i) comparative stripping solutions and (ii) solutions according to the disclosed and claimed subject matter that were evaluated with low temperature cured polyimide (PI) films. These tests were performed using semiconductor wafers patterned with cured PI films. For the immersion process, coupon-sized samples of semiconductor wafers were processed in beakers. Beakers were filled with 100 grams of a stripping solution and heated to the target temperature. When the stripping solution was at the process temperature, a coupon was placed in a holder in the beaker, and slight agitation was provided by a stir bar. Temperature was maintained at the process temperature throughout the process. After a total processing time of 90 minutes, the coupons were removed from the beaker, rinsed with DI water and IPA, and dried with a stream of nitrogen.

The pattern of the PI films was monitored using optical microscope and scanning electronic microscope before and after processing for each coupon that was tested. Any cracks or visible damages on film surface were noted as an indicator of poor compatibility of PI. All examples according to the disclosed and claimed subject matter except example 13 had good compatibility with PI after 90 minutes while the comparative example 1 showed PI attack.

TABLE 7
PI Compatibility

| | Comp. | Comp. | | | | | | | |
|---|---|---|---|---|---|---|---|---|---|
| Ex. | 1 | 2 | 1 | 8 | 9 | 10 | 11 | 12 | 13 |
| KOH | 1.8 | 2.03 | 2.03 | 1.1 | — | 1.05 | 2.03 | 2.03 | 2.03 |
| NaOH | — | — | — | — | 2.05 | 1.0 | — | — | — |
| MEA | 8 | — | — | — | — | — | — | — | — |
| PG | — | 12.75 | 12.75 | 12.75 | 12.75 | 12.75 | 12.75 | 12.75 | 12.75 |
| MMB | 20 | — | — | — | — | — | 69.5 | — | — |
| DB | 65 | — | — | — | — | — | — | 69.5 | — |
| BA | — | — | — | — | — | — | — | — | 69.5 |
| TEGME | — | 70 | 69.5 | 70.65 | 69.65 | 69.56 | — | — | — |
| DEG | 5 | 15 | 15 | 15 | 15 | 15 | 15 | 15 | 15 |
| Cu Nitrate | 0.01 | — | — | — | — | — | — | — | — |
| Sorbitol | — | — | 0.5 | 0.5 | 0.5 | 0.5 | 0.5 | 0.5 | 0.5 |
| Total | 99.81 | 99.78 | 99.78 | 99.88 | 99.95 | 99.86 | 99.78 | 99.78 | 99.78 |
| Temp./° C. | 80 | 80 | 80 | 80 | 80 | 80 | 80 | 80 | 80 |
| Time/min | 90 | 90 | 90 | 90 | 90 | 90 | 90 | 90 | 90 |
| PI | Attack | No | No | No | No | No | No | No | Attack |
| | | attack | attack | attack | attack | attack | attack | attack | |

Although the disclosed and claimed subject matter has been described and illustrated with a certain degree of particularity, it is understood that the disclosure has been made only by way of example, and that numerous changes in the conditions and order of steps can be resorted to by those skilled in the art without departing from the spirit and scope of the disclosed and claimed subject matter. Thus, it will be understood by those skilled in the art that various changes may be made, and equivalents may be substituted for elements thereof without departing from the scope of the disclosed and claimed subject matter. In addition, many modifications may be made to adapt a particular situation or material to the teachings of the disclosed and claimed subject matter without departing from the essential scope thereof. In addition, all numerical values identified in the detailed description shall be interpreted as though the precise and approximate values are both expressly identified.

1. A photoresist stripper solution comprising:
(i) about 1.0 wt % to about 2.5 wt % of one or more neat inorganic base;
(ii) about 90 wt % to about 97 wt % of two or more organic solvents that are different from one another comprising (a) a first solvent that comprises one or more of a glycol ether solvent, an ether alcohol solvent and an aromatic ring-containing alcohol solvent or mixtures thereof and (b) a second solvent that comprises one or more polyol solvent;
(iii) about 0.01 wt % to about 2 wt % of one or more corrosion inhibitors; and
(iv) optionally one or more secondary solvent(s),
wherein the total wt % of components (i), (ii), (iii) and (iv) is equal to or less than 100 wt %.

2-4. (canceled)

5. The photoresist stripper solution of claim 1, wherein the one or more neat inorganic bases comprises about 1.75 wt % to about 2.25 wt % of neat KOH.

6-17. (canceled)

18. The photoresist stripper solution of claim 1, wherein the one or more neat inorganic bases comprises one or more of sodium hydroxide, potassium hydroxide, lithium hydroxide, rubidium hydroxide and cesium hydroxide.

19. (canceled)

20. The photoresist stripper solution claim 1, wherein the two or more organic solvents comprise (a) a first solvent that comprises about 60 wt % to about 80 wt % of one or more of an ether alcohol, an aromatic ring-containing alcohol solvent or mixtures thereof and (b) a second solvent that comprises about 10 wt % to about 30 wt % of one or more polyol solvent, and
wherein the first solvent and the second solvent are different from one another.

21. (canceled)

22. (canceled)

23. The photoresist stripper solution claim 1, wherein the two or more organic solvents comprise (a) about 60 wt % to about 80 wt % a first solvent that comprises of triethylene glycol monomethyl ether (TEGME) and (b) about 10 wt % to about 30 wt % a second solvent that comprises one or more of ethylene glycol (EG), diethylene glycol (DEG), triethylene glycol (TEG), glycerol, propylene glycol (PG) and mixtures thereof, and
wherein the first solvent and the second solvent are different from one another.

24. (canceled)

25. (canceled)

26. The photoresist stripper solution of claim 1, wherein the one or more corrosion inhibitors comprises one or more of BZT, sorbitol, resorcinol, sebacic acid, glycerol and copper (II) nitrate.

27. The photoresist stripper solution of claim 1, wherein the one or more corrosion inhibitors comprises about 0.5 wt % to about 1 wt % of BZT.

28. (canceled)

29. (canceled)

30. The photoresist stripper solution of claim 1, wherein the one or more corrosion inhibitors comprises about 0.2 wt % to about 1 wt % of sorbitol.

31-33. (canceled)

34. The photoresist stripper solution of claim 1, wherein the one or more corrosion inhibitors comprises about 0.2 wt % to about 1 wt % of resorcinol.

35-37. (canceled)

38. The photoresist stripper solution of claim 1, wherein the one or more corrosion inhibitors comprises about 0.2 wt % to about 1 wt % of glycerol.

39-41. (canceled)

42. The photoresist stripper solution of claim 1, wherein the one or more corrosion inhibitors comprises about 0.2 wt % to about 1 wt % of sebacic acid.

43-45. (canceled)

46. The photoresist stripper solution of claim 1, wherein the one or more corrosion inhibitors comprises about 0.005 wt % to about 1 wt % of copper nitrate.

47-49. (canceled)

50. The photoresist stripper solution of claim 1, wherein the solutions are free of an amide-containing solvent.

51. The photoresist stripper solution of claim 1, wherein the solutions are free of a sulfur containing solvent.

52. The photoresist stripper solution of claim 1, wherein the solutions are free of dimethyl sulfoxide (DMSO).

53. The photoresist stripper solution of claim 1, wherein the solutions are free of n-methyl-2-pyrrolidone (NMP).

54. The photoresist stripper solution of claim 1, wherein the solutions are free of dimethyl sulfoxide (DMSO) and n-methyl-2-pyrrolidone (NMP).

55. (canceled)

56. The photoresist stripper solution claim 1, further comprising the secondary solvent, wherein the secondary solvent comprises water.

57. (canceled)

58. (canceled)

59. The photoresist stripper solution of claim 1, comprising about 2.03 wt % of KOH, about 12.75 wt % of propylene glycol, about 69.5 wt % of triethylene glycol monomethyl ether and about 15 wt % diethylene glycol and about 0.5 wt % sorbitol.

60. A method for removing a photoresist or similar material from a substrate comprising the steps of:
(i) contacting the substrate with one or more of the photoresist stripper solutions of claim 1 for a time sufficient to remove a desired amount of the photoresist or similar material,
(ii) removing the substrate from the stripping solution,
(iii) rinsing the stripping solution from the substrate with DI water or a solvent, and
(iv) optionally drying the substrate.
